(19) United States
(12) Patent Application Publication
(10) Pub. No.: US 2020/0103526 A1
(43) Pub. Date: Apr. 2, 2020

(54) TIME OF FLIGHT SENSOR

(71) Applicant: Photonic Vision Limited, Sevenoaks Kent (GB)

(72) Inventor: Christopher John MORCOM, Westbere Kent (GB)

(73) Assignee: Photonic Vision Limited, Sevenoaks Kent (GB)

(21) Appl. No.: 16/495,831

(22) PCT Filed: Mar. 21, 2018
(86) PCT No.: PCT/GB2018/050727

§ 371 Date: Sep. 20, 2019

(30) Foreign Application Priority Data
Mar. 21, 2017 (GB) 1704443.9

(51) Int. Cl. G01S 17/36; H01L 27/148; G01S 17/89; G01S 7/486

(52) U.S. Cl. CPC G01S 17/36; G01S 7/4863; G01S 17/89; H01L 27/148

(57) ABSTRACT

A time of flight distance measurement system has a light emitter (8) emitting a pulsed fan beam and a time of flight sensor (6) which may be a CCD with a photosensitive image region, a storage region not responsive to light and a readout section. Circuitry is arranged to control the time of flight sensor (6) to capture image data of the pulsed illumination stripe along a row of pixels and to transfer the captured image data to the storage section. The circuitry adjusts the phase of the clocking of the image region with respect to the emission of a pulsed fan beam to collect a plurality of image illumination stripes at a respective plurality of phase shifts; and a processor combines the data from the plurality of image illumination stripes at the plurality of phase shifts to determine the distance to the object.

### FIELD OF INVENTION

The invention relates to a time of flight distance sensor and method of use.

### BACKGROUND TO THE INVENTION

Accurate and fast surface profile measurement is a fundamental requirement for many applications including industrial metrology, machine guarding and safety systems.

Automotive driver assistance and collision warning systems pose specific measurement challenges because they require long range (>100 m) distance measurement with both high precision and high spatial resolution.

Time of flight based light radar (lidar) sensors are a promising technology to deliver this combination of capabilities but existing solutions are costly and have yet to deliver the required performance particularly when detecting objects of low reflectivity.

To address this problem, much effort has been expended on developing pixelated focal plane arrays able to measure the time of flight of modulated or pulsed infra-red (IR) light signals and hence measure 2D or 3D surface profiles of remote objects. A common approach is to use synchronous or “lock-in” detection of the phase shift of a modulated illumination signal. In the simplest form of such devices, electrode structures within each pixel create a potential well that is shuffled back and forth between a photosensitive region and a covered region. By illuminating the scene with a modulated light source (either sine wave or square wave modulation has been used) and synchronising the shuffling process with the modulation, the amount of charge captured in each pixel's potential well is related to the phase shift and hence distance to the nearest surface in each pixel's field of view. By using charge coupled device technology, the shuffling process is made essentially noiseless and so many cycles of modulation can be employed to integrate the signal and increase the signal to noise ratio. This approach with many refinements is the basis of the time of flight focal plane arrays manufactured by companies such as PMD, Canesta (Microsoft) and Mesa Imaging.

However, whilst such sensors can provide high spatial resolution their maximum range performance is limited by random noise sources including intrinsic circuit noise and particularly the shot noise generated by ambient light. Furthermore, the covered part of each pixel reduces the proportion of the area of each pixel able to receive light (the “fill factor”). This fill factor limitation reduces the sensitivity of the sensor to light, requiring a higher power and costlier light source to overcome. An additional an important limitation is that this technique is limited to providing only one measurement of distance per pixel and so is unable to discriminate the reflections from solid objects and atmospheric obscurants such as fog, dust, rain and snow thus restricting the use of such sensors technologies to indoor, covered environments.

To overcome these problems companies such as Advanced Scientific Concepts Inc. have developed solutions whereby arrays of avalanche photodiodes (APD) are bump bonded to silicon readout integrated circuits (ROIC) to create a hybrid APD array/ROIC time of flight sensor. The APDs provide gain prior to the readout circuitry thus helping to reduce the noise contribution from the readout circuitry whilst the ROIC captures the full time of flight signal for each pixel allowing discrimination of atmospheric obscurants by range. In principle, by operating the ROIC at a sufficiently high clock frequency this architecture can also achieve good temporal and hence distance precision. However, the difficulties and costs associated with manufacturing dense arrays of APDs and the yield losses incurred when hybridising them with ROIC has meant that the resolution of such sensors is limited (e.g. 256×32 pixels) and their prices are very high.

Some companies have developed systems using arrays of single photon avalanche detectors (SPAD) operated to detect the time of flight of individual photons. A time discriminator circuit (TDC) is provided to log the arrival time of each photon. Provided the TDC is operated at sufficiently high frequency, then such sensors are capable of very good temporal and hence range resolution. In addition, such sensors can be manufactured at low cost using complementary metal-oxide semi-conductor (CMOS) processes. However, the quantum efficiency of such sensors is poor due to constraints of the CMOS process and their fill factor is poor due to the need for TDC circuitry at each pixel leading to very poor overall photon detection efficiency despite the very high gain of such devices. Also avalanche multiplication based sensors can be damaged by optical overloads (such as from the sun or close specular reflectors in the scene) as avalanche multiplication in the region of the optical overload signal can lead to extremely high current densities, risking permanent damage to the device structure.

An alternative approach that has been attempted is to provide each pixel with its own charge coupled or CMOS switched capacitor delay line, integrated within the pixel, to capture the time of flight signal. An advantage of this approach is that the time of flight can be captured at a high frequency to provide good temporal and hence range resolution, but the signal read-out process can be made at a lower frequency, allowing a reduction in electrical circuit bandwidth and hence noise. However, if the delay lines have enough elements to capture the reflected laser pulse from long range objects with good time and hence distance resolution, then they occupy most of the pixel area leaving little space for a photosensitive area. Typically, this poor fill factor more than offsets the noise benefits of the slower speed readout and so high laser pulse power is still required, significantly increasing the total lidar sensor cost. To try to overcome this problem some workers have integrated an additional amplification stage between the photosensitive region and the delay line but this introduces noise itself, thus limiting performance.

Thus, there is a need for a solution able to offer a combination of long range operation with high spatial resolution and high range measurement precision.

### SUMMARY OF THE INVENTION

According to the invention, there is provided a method of operating a time of flight sensor according to claim 1.

The inventor has realised that by combining a particular sensor architecture with a novel operating method the poor fill factor and high readout noise problems of the existing sensors can be overcome to enable long range operation with high measurement precision in a very low cost and commercially advantageous manner.

The method may in particular include
(i) emitting a pulsed fan beam from a light emitter to illuminate a remote object with an object illumination stripe;
(ii) capturing an image of the object illumination stripe as an image illumination stripe on a photosensitive image region of a time of flight sensor comprising an array of M columns of J rows of pixels, where both M and J are positive integers greater than 2,
(iii) transferring data from the photosensitive image region to a storage region arranged not to respond to incident light, the storage region comprising M columns of S storage elements, along the M columns of the storage region from respective columns of the photosensitive image region at a transfer frequency F_{T};
(iv) reading out data in a readout section from the M columns of the storage region; and
(v) clocking the image region at a clock frequency while capturing the image of the object illumination stripe,
(vi) wherein the method further comprises adjusting the phase of the clocking of the image region with respect to the step of emitting a pulsed fan beam to collect a plurality of image illumination stripes at a respective plurality of phase shifts;
(vii) reading out the data from the plurality of image illumination stripes from the image region via the storage region and the readout section; and
(viii) combining the data from the plurality of image illumination stripes at the plurality of phase shifts to determine the distance to the object.

In a particular embodiment, adjusting the phase may comprise repeating steps (i) to (v) P times, where P is a positive integer, by introducing a variable phase Δθ of the clocking of the fan beam for each of Δθ=0, 1/P, 2/P . . . (P−1)/P.

Adjusting the phase may include introducing a variable delay

$$Δ T ( i ) = \frac{i}{P * {F}_{T}}$$

into the clocking of the image pulse, and repeating the step of emitting the clock pulse P times, for each of i=1 to P,
where i is a positive integer from 1 to P, P is a positive integer being the number of different variable delays used.

In a particular embodiment,
a first light pulse is emitted at time T0;
the image and store sections are clocked at frequency F_{T} to transfer charge captured in the image section along each column and into the store section;
after P image and store section clock pulses have been applied to the image and store sections, the control electronics causes the light source to emit a second pulse at time T(i) where:

$$T ( i ) = T 0 + \frac{P}{{F}_{T}} + Δ T ( i )$$

and these steps are repeated every P clock pulses incrementing delay index value i each time until a total of P pulses have been emitted.

The method may include, after reading out the data via the readout section, combining the data for each of the P pulses to create a data set T(X,uR) where the temporal resolution of the signal captured for the reflected pulse in each column (X) has been improved by a factor P.

The method may also include clearing the image and storage sections before step (i).

In another aspect, the method relates to a time of flight distance measurement system, comprising:
a light emitter arranged to emit a pulsed fan beam for illuminating a remote object with a pulsed illumination stripe;
a time of flight sensor comprising:
a photosensitive image region comprising an array of M columns of P rows of pixels, where both M and P are positive integers greater than 2, arranged to respond to light incident on the photosensitive image region;
a storage region arranged not to respond to incident light, the storage region comprising M columns of N storage elements, arranged to transfer data along the M columns of storage from a respective one of the M pixels along column of N storage elements; and
a readout section arranged to read out data from the M columns of the storage region; and
circuitry for controlling the time of flight sensor to capture image data of the pulsed illumination stripe along a row of pixels and to transfer the captured image data to the storage section;
wherein the circuitry is arranged to adjust the phase of the clocking of the image region with respect to the step of emitting a pulsed fan beam to collect a plurality of image illumination stripes at a respective plurality of phase shifts; and
a processor arranged to combine the data from the plurality of image illumination stripes at the plurality of phase shifts to determine the distance to the object.

The time of flight sensor may be a charge coupled device. The use of a charge coupled device allows for a very high fill factor, i.e. a very large percentage of the area of the image section of the time of flight sensor may be sensitive to light. This increases efficiency, and allows for the use of lower power lasers.

In particular embodiments, photons incident over at least 90% of the area of the photosensitive image region are captured by the photosensitive image region.

In another aspect, the invention relates to a computer program product, which may be recorded on a data carrier, arranged to control a time of flight distance measurement system as set out above to carry out a method as set out previously.

### BRIEF DESCRIPTION OF THE DRAWINGS

FIG. 1 illustrates a first embodiment of the invention;

FIG. 2 illustrates recording an image on a focal plane array arrangement;

FIG. 3 illustrates data at a plurality of different phase shifts;

FIG. 4 illustrates combined data;

FIG. 5 illustrates a detail of preferred embodiments of the invention;

FIG. 6 illustrates a second embodiment of the invention;

FIG. 7 illustrates data captured in a particular column (X=72) by the second embodiment of the invention;

FIG. 8 illustrates combined data from the second embodiment.

The figures are schematic and not to scale.

### DETAILED DESCRIPTION

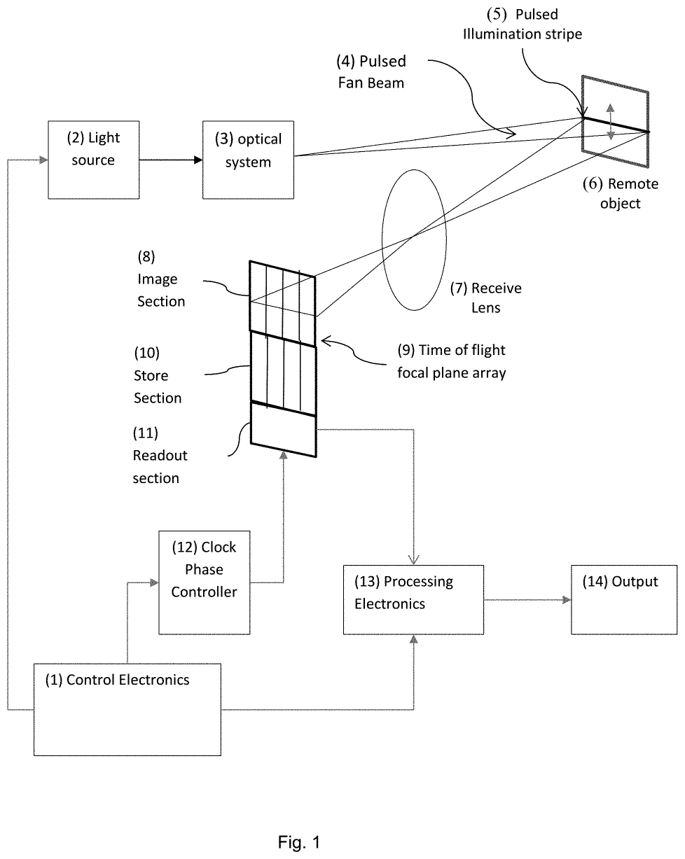

One embodiment is shown in FIG. 1.

Control electronics (1) are configured to control light source (2) and associated optical system (3) to emit a pattern of light with a pre-defined combination of spatial and temporal characteristics into the far field.

In the simplest embodiment shown in FIG. 1, the spatial distribution of the emitted light is a fan beam (4) whose location in a direction orthogonal to the long axis of the beam is adjustable under control of the control electronics (1) and the temporal characteristics of the light are a short pulse, where the timing of the light pulse is set by the control electronics (1).

This combination of spatial and temporal characteristics will create a pulsed stripe of illumination (5) across the surface of any remote object (6).

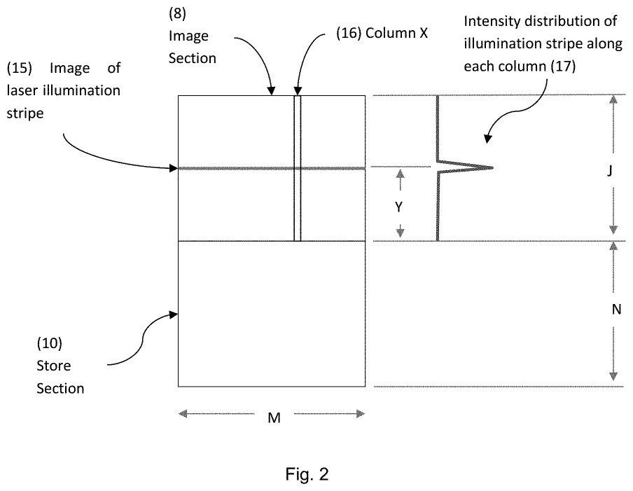

Receive lens (7) is configured to collect and focus the reflected pulse of light from this stripe of illumination (5) onto the photosensitive image section (8) of a focal plane array (FPA) device (9) yielding a stripe of illumination (15) on the surface of the image area as illustrated schematically in FIG. 2.

It will be appreciated by those skilled in the art that the optical arrangement may be more complex than a single receive lens (7) and any optical system capable of focussing the object illumination stripe onto the image section (8) to achieve the image illumination stripe may be used.

By shifting the position of the fan beam under control of the control electronics (1), the vertical position of the intensity distribution at the image plane is also controllable.

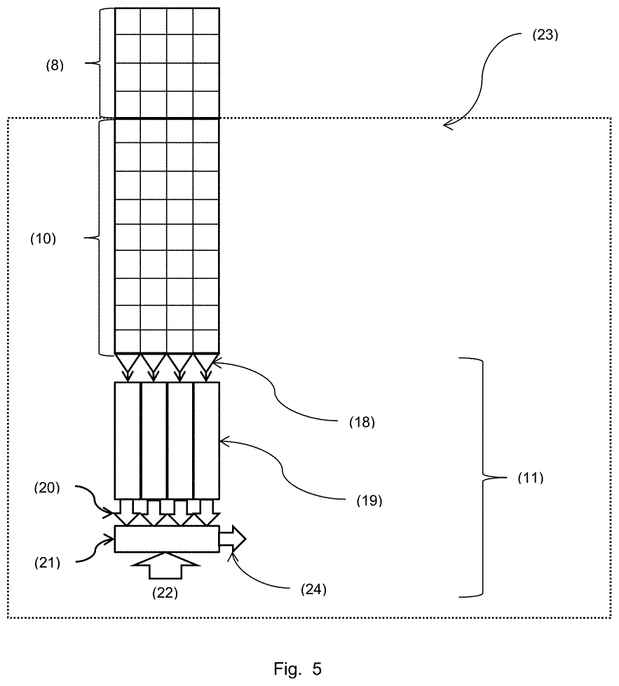

As illustrated in FIG. 5, the image (8) section of the focal plane array (9) comprises an array of M columns and J rows of photosensitive pixels. The focal plane array device (9) also contains a store section (10) and readout section (11).

The store section (10) comprises M columns by N rows of elements and is arranged to be insensitive to light. The image and store sections are configured so that charge packets generated by light incident upon the pixels in the image section can be transferred along each of the M columns from the image section (8) into the corresponding column of the store section (10) at a transfer frequency F_{T} by the application of appropriate clock signals from the control electronics (1). A clock phase controller (12) enables the starting phase fraction a of the image and store section clock signals to be set by the control electronics (1). The starting phase fraction is defined by:

$$Δθ = \frac{{θ}_{S}}{2 π}$$

### Where:

θ_{S}=Starting phase of the image and store section clock sequence expressed in radians

The readout section (11) is arranged to readout data from the M columns of the storage region at a readout frequency F_{R} and is also configured to be insensitive to light.

The sequence of operation is as follows:
a) control electronics (1) commands the light source (2) and optical system (3) to set the location of the horizontal fan beam so that any light from the pulsed illumination stripe (5) that is reflected from a remote object (6) will be focussed by lens (7) upon the image section (8) as a corresponding stripe (15) centred upon row Y as illustrated schematically in FIG. 2. This means that each column X (16) of the sensor will see an intensity distribution (17) with a peak centred at row Y.
b) The control electronics then operates image and store sections (8) and (1) to clear all charge from within them.
c) The control electronics (1) commands the clock phase controller (12) to set the starting phase fraction AO of the image and store section clock sequences to zero.
d) The control electronics then causes light source (1) to emit a light pulse and commences clocking the image (8) and store (10) sections at high frequency F_{T} to transfer charge captured in the image section (8) along each column and into the store section (10). Using its apriori knowledge of Y, the control electronics (1) applies a total of N+Y clock cycles to the image and store sections.
   Whilst the image and store sections are being clocked, the pulsed fan beam (5) propagates outwards from the sensor and will be reflected by remote objects (6) within its path. Such reflected light is collected by receive lens (7) and focussed onto the image area (8). As the reflected and captured parts of the fan beam light pulse are incident upon the image section (8) they will generate charge packages in columns X (16) along row Y at a point in time equal to the time of flight TOF(X) of that part of the fan beam that is incident upon an individual column X.
e) The clocking of the image and store sections causes the charge packages captured at instant TOF(X) to be moved down each column X (16) in a direction towards the store section, creating a spatially distributed set of charge packages within the store section, where the location of the centre of each charge packages R(X) is determined by the time of flight (TOF(X)) of the reflected light from a remote object (6) at the physical location in the far field corresponding to the intersection of column X and row Y plus the starting phase Δθ of the image and store section fast transfer clock sequence and is given by:

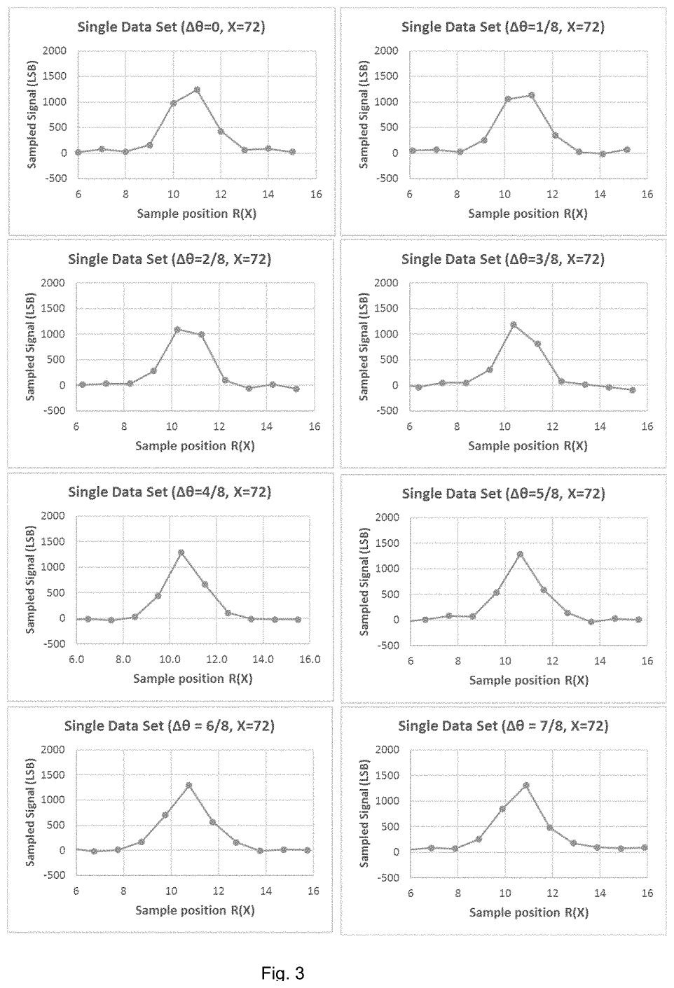

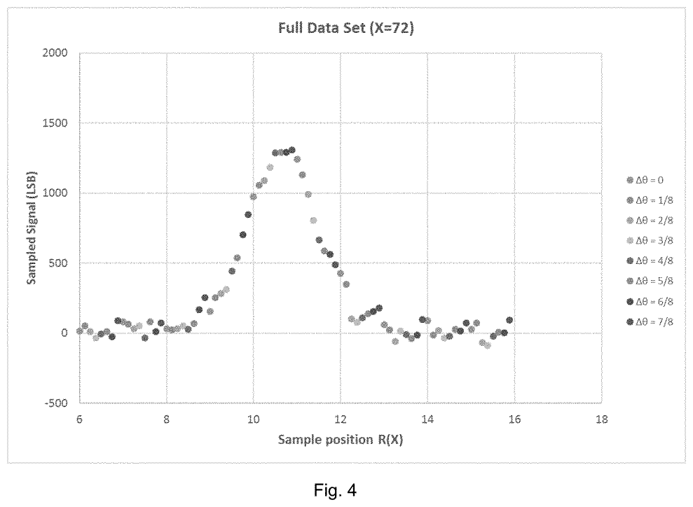

R(X)=TOF(X)·F_{T}+Δθ
f) The control electronics then applies clock pulses to the store (10) and readout sections (11) to readout the captured packages of charge, passing them to processing electronics (13) where a complete frame of N by M elements of captured data is stored.
g) The control electronics then repeats steps a) to g) sequentially for a further (P−1) occasions incrementing the starting phase fraction a by 1/P to capture a total of P data frames where each frame is shifted in phase by P/2π. FIG. 3 illustrates the result of this process for P=8 and shows the data captured from column X=72 in each of the eight successive data frames.
h) The processing electronics then interleaves the data from all P data frames to yield a high-resolution data set for each column X, as illustrated in FIG. 4 from the data shown in FIG. 3 for column X=74.
i) The processing electronics (13) then uses standard mathematical techniques such as centroiding or edge detection to calculate the precise location of the reflection R_{P}(X) from the interleaved set of P data frames. From the speed of light (c) the processing electronics calculates the distance D(X,Y) to each remote object (6) illuminated by the fan beam (4) from the following equation:

$$D ( X , Y ) = \frac{{cR}_{P} ( X )}{2 {F}_{T}} \qquad Equation 1$$

j) The control electronics then repeats steps a) to j) sequentially moving the position of the far field illumination stripe (5) to illuminate a different part of the remote objects (6) and hence receiving an image of the laser illumination stripe (15) at a different row Y allowing the sensor to build up a complete three dimensional point cloud comprising a set of distance data points D(X,Y) that is made accessible via sensor output (14).

It can be seen that this method of operation of the focal plane array, where the relative phase of the emitted laser pulse timing and the high frequency image and store section clock sequence for each measurement is sequentially shifted, has enabled the sensor to capture the signal from each reflection with a sampling frequency that is effectively P times higher than F_{T}, allowing a significant improvement in the distance measurement precision.

It can also be seen that this method of operation and the separation of the detector architecture into image, store and readout sections enables the whole of each image pixel to be photosensitive (i.e. 100% fill factor) because the charge to voltage conversion/readout process is physically remote on the detector substrate. In addition, the use of a store section enables the charge to voltage conversion/readout process to be carried out at a different time to the photon capture process.

These two factors deliver very significant benefits over all other time of flight sensors that are constrained by the necessity for photon capture, charge to voltage conversion and, in some cases, time discrimination to occur within each pixel.
i. The physical separation of the image section enables it to be implemented using well-known, low cost and highly optimised monolithic image sensor technologies such as charge coupled device (CCD) technology. This allows noiseless photon capture and transfer and, in addition to the 100% fill factor, very high quantum efficiency through the use of techniques such as back-thinning, back surface treatment and anti-reflection coating.
ii. The temporal separation of the high-speed photon capture and charge to voltage/readout process and the physical separation of the readout circuitry allows the readout circuitry and readout process to be fully optimised independent of the high-speed time of flight photon capture process. For example the readout of the time of flight signal can be carried out at a significantly lower frequency (F_{R}) than its original high speed capture (F_{T}). This allows the noise bandwidth and hence the readout noise to be significantly reduced, but without the very poor fill factor and hence sensitivity losses encountered by other approaches that also seek to benefit from this option.

The significance of these benefits is such that an optimised light radar sensor can provide long range, high resolution performance without needing costly and complicated avalanche multiplication readout techniques.

In a preferred embodiment shown in FIG. 5, the readout electronics (11) are configured to allow readout from all columns to be carried out in parallel. Each column is provided with a separate charge detection circuit (17) and analogue to digital converter (18). The digital outputs (19) of each analogue to digital converter are connected to a multiplexer (20) that is controlled by an input (21) from the control electronics.

The store (10) and readout (11) sections are covered by an opaque shield (22).

In operation, the control electronics applies control pulses to the store section (10) to sequentially transfer each row of photo-generated charge to the charge detectors (17). These convert the photo-generated charge to a voltage using standard CCD output circuit techniques such as a floating diffusion and reset transistor. The signal voltage from each column is then digitised by the analogue to digital converters (18) and the resultant digital signals (19) are sequentially multiplexed to an output port (23) by the multiplexor (20) under control of electrical interface (21).

By carrying out the sensor readout for all columns in parallel, this architecture minimises the operating readout frequency (F_{R}) and hence readout noise.

For some applications, it is useful to implement the relative phase shift by adjusting the timing of the laser pulse with respect to the image and store section clock sequence.

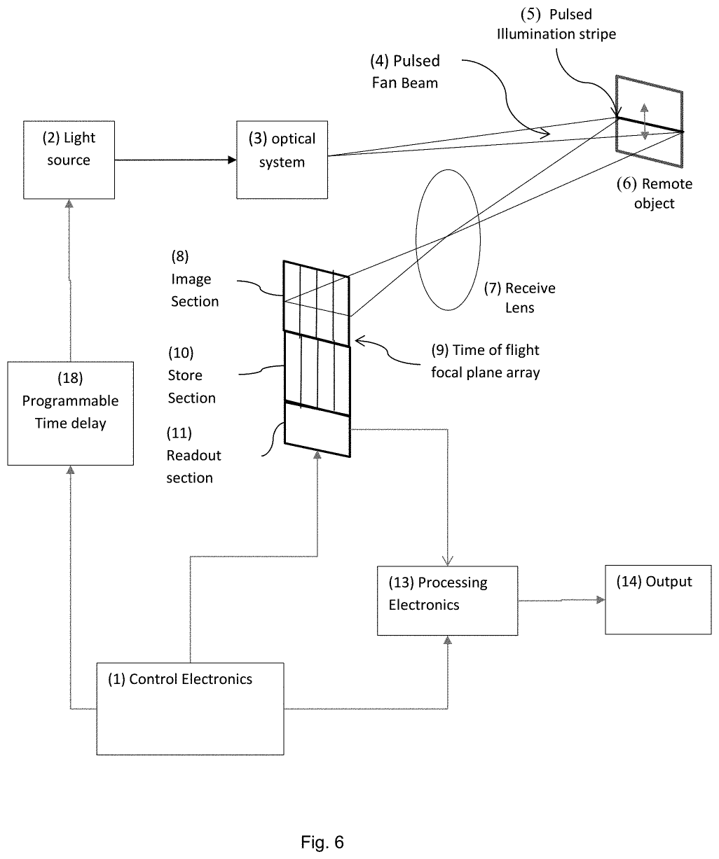

One embodiment that uses this approach to improve the precision of distance measurement for fast moving remote objects will be explained with reference to FIG. 6.

Here, a programmable time delay generator (18) is provided to introduce a precise delay ΔT(i) into the timing of the light pulse that is equal to a fraction of the image and store section clock period where:

$$Δ T ( i ) = \frac{i}{P * {F}_{T}}$$

Delay index number (i) is controllable by the control electronics (1).

The sequence of operation is as follows:
a) control electronics (1) commands the light source (2) and optical system (3) to set the location of the horizontal fan beam so that any light from the pulsed illumination stripe (5) that is reflected from a remote object (6) will be focussed by lens (7) upon the image section (8) as a corresponding stripe (15) centred upon row Y as illustrated schematically in FIG. 2. This means that each column X (16) of the sensor will see an intensity distribution (17) with a peak centred at row Y from a corresponding point on any far objects (6).
b) The control electronics initially sets delay index i to be equal to zero (i=0).
c) The control electronics then operates image and store sections (8) and (1) to clear all charge from within them.
d) The control electronics causes light source (1) to emit a first light pulse at time T0 and commences clocking the image (8) and store (10) sections at high frequency F_{T} to transfer charge captured in the image section (8) along each column and into the store section (10).
e) After P image and store section clock pulses have been applied to the image and store sections, the control electronics causes the light source to emit a second pulse that, due to the action of the programmable time delay circuit (18), will be emitted at time T(i) where:

$$T ( i ) = T 0 + \frac{P}{{F}_{T}} + Δ T ( i )$$

f) The control electronics repeats step e), incrementing delay index value i each time until a total of P pulses have been emitted.
g) Using its apriori knowledge of Y, the control electronics applies a total of N+Y clock cycles to the image and store sections.
h) Whilst the image and store sections are being clocked, each pulse of light emitted at Time T(i) propagates out as a fan beam (5), reflects of remote objects (6) and is focussed onto the image area (8) to generate a charge package in column X along row Y at time T1(X,i) given by:

T1(X,i)=TOF(X)+T(i)
where TOF(X) is the time of flight of that part of the fan beam that is reflected off a far object and focused upon an individual column X.
i) The clocking of the image and store sections causes the charge packages to be moved N+Y rows down each column in a direction towards the store section, creating a number P of spatially distributed charge packages within each column X of the store section.
   It will be seen that the physical position R(X,i) of each of the P charge packages in column X will be given by:

$$R ( X , i ) = {F}_{T} * TOF ( X ) + P + \frac{i}{P}$$

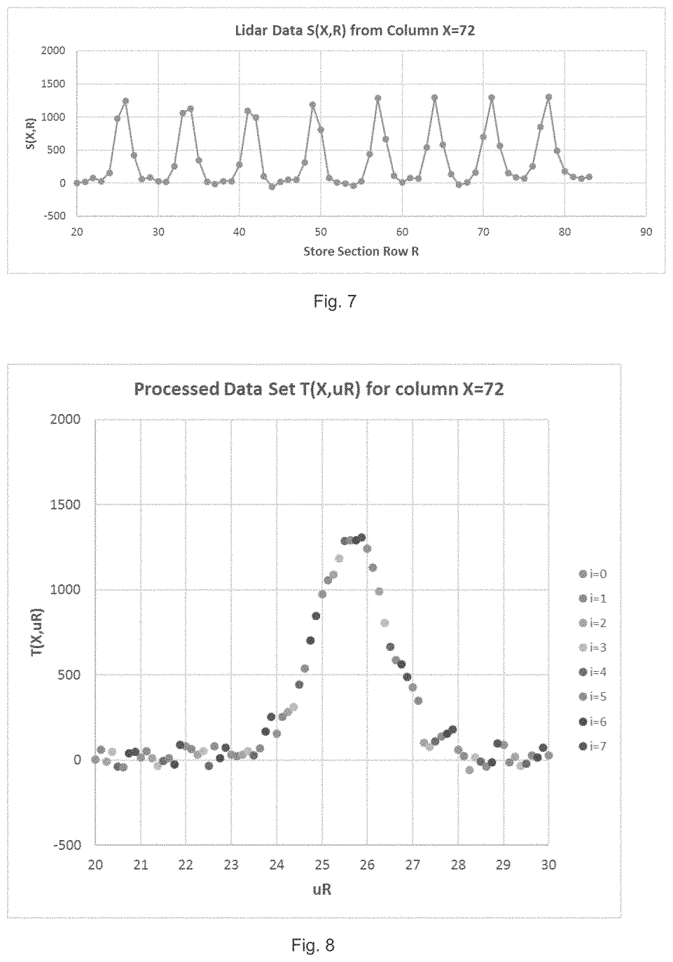

j) The control electronics then applies clock pulses to the store (10) and readout sections (11) to readout the captured packages of charge, passing them to processing electronics (13) which stores the captured data set S(X,R), where X is the column number and R is the row number of the corresponding store section element.
k) FIG. 7 shows the resultant column data S(X,R) captured from column X=72 for the case P=8 in which the reflected signals captured from each of the eight separate pulses can be seen.
l) Processing electronics (13) then calculates a new data set T(X,uR) where each sample T(X,uR) in the data set is derived from data set S(X,R) using an algorithm that may be expressed using the following pseudo code:

For x = 0 to (M−1)

For R = 0 to (N−1)

For i = 0 to (P−1)

uR = R + i/P
pR = R + i * P
T(X,uR) = S(X,pR)

Next i

Next R

Next X

FIG. 8 shows the resultant data set T(X,uR) from the example signal in FIG. 7 and shows that the action of the algorithm above is to combine the data from the separate phase shifted pulses within the original data set S(X,R) to create a data set T(X,uR) where the temporal resolution of the signal captured for the reflected pulse in each column (X) has been improved by a factor P.
k) Processing electronics (13) then employs standard techniques such as thresholding and centroiding to detect and find the precise location R(X) of the centre of the high resolution, composite of the reflected, captured pulses from a remote object (6) at the physical location in the far field corresponding to the intersection of column X and row Y.
l) The control electronics then repeats steps a) to l) sequentially moving the position of the far field illumination stripe (5) to illuminate a different part of the remote objects (6) to gather sets of distance measurements R(X) each corresponding to different row locations Y and hence allowing the sensor to build up a complete three dimensional point cloud comprising a set of distance data points S(X,Y) that is made accessible via sensor output (14).

In this case, it will be appreciated that, rather than waiting for each data set to captured and readout, by issuing multiple pulses within the fast readout time, the time period between adjacent pulses is kept very short, preventing a loss of accuracy when measuring distance to fast moving objects.

It will be appreciated by those skilled in the art that the algorithm described above can be considerably improved. For example, to reduce computation the processing electronics (13) could look for the first sample point along column X that exceeds a pre-defined threshold and then the algorithm is used to compute the high-resolution data set from the next P×P data points (i.e. 64 data points if P=8) rather than applying to algorithm to all N data points in each column.

Those skilled in the art will realise that the invention may be implemented in ways other than those described in detail above. For example, the control electronics 12,16 and the processing electronics 13,17 may in practice be implemented by a single processor or a network running code adapted to carry out the method as described above. In other embodiments, the control electronics and processing electronics may be implemented as separate devices.

1. A time of flight distance measurement method comprising:
(i) emitting a pulsed fan beam from a light emitter to illuminate a remote object with an object illumination stripe;
(ii) capturing an image of the object illumination stripe as an image illumination stripe on a photosensitive image region (8) of a time of flight sensor comprising an array of M columns of J rows of pixels, where both M and J are positive integers greater than 2;
(iii) transferring data from the photosensitive image region (1,50) to a storage region (2) arranged not to respond to incident light, the storage region comprising M columns of S storage elements, along the M columns of the storage region from respective columns of the photosensitive image region at a transfer frequency F_{T};
(iv) reading out data in a readout section (3) from the M columns of the storage region (2); and
(v) clocking the image region at a clock frequency while capturing the image of the object illumination stripe;
(vi) wherein the method further comprises adjusting the phase of the clocking of the image region with respect to the step of emitting a pulsed fan beam to collect a plurality of image illumination stripes at a respective plurality of phase shifts;
(vii) reading out the data from the plurality of image illumination stripes from the image region (1,50) via the storage region and the readout section; and
(viii) combining the data from the plurality of image illumination stripes at the plurality of phase shifts to determine the distance to the object.

2. A time of flight distance measurement method according to claim 1, wherein:
adjusting the phase comprises repeating steps (i) to (v) P times, where P is a positive integer, by introducing a variable phase Δθ of the clocking of the fan beam for each of Δθ=0, 1/P, 2/P . . . (P−1)/P.

3. A method according to claim 1, wherein adjusting the phase comprises introducing a variable delay
$$Δ T ( i ) = \frac{i}{P * {F}_{T}}$$
into the clocking of the image pulse, and repeating the step of emitting the clock pulse P times, for each of i=1 to P,
where i is a positive integer from 1 to P, P is a positive integer being the number of different variable delays used.

4. A method according to claim 3, wherein
a first light pulse is emitted at time T0;
the image (8) and store (10) sections are clocked at frequency F_{T} to transfer charge captured in the image section (8) along each column and into the store section (10);
after P image and store section clock pulses have been applied to the image and store sections, the control electronics causes the light source to emit a second pulse at time T(i) where:
$$T ( i ) = T 0 + \frac{P}{{F}_{T}} + Δ T ( i )$$
and repeating every P clock pulses incrementing delay index value i each time until a total of P pulses have been emitted.

5. A method according to claim 4, further comprising, after reading out the data via the readout section,
combining the data for each of the P pulses to create a data set T(X,uR) where the temporal resolution of the signal captured for the reflected pulse in each column (X) has been improved by a factor P.

6. A method according to claim 5, wherein combining the data comprises carrying out the method to obtain new data array T(X,uR), where X is from 0 to M−1 and R is from 0 to N−1 from original data array S(X,R), where S(X,R) is the data read out at readout cycle R from column X:
For X = 0 to (M−1)
For R = 0 to (N−1)
For i = 0 to (P−1)
uR = R + i / P
pR = R + i * P
T(X,uR) = S(X,pR)
Next i
Next R
Next X

7. A method according to claim 1, further comprising clearing the image and storage sections before step (i).

8. A time of flight distance measurement system, comprising:
a light emitter (8) arranged to emit a pulsed fan beam for illuminating a remote object with a pulsed illumination stripe;
a time of flight sensor (6) comprising:
a photosensitive image region (1,50) comprising an array of M columns of P rows of pixels, where both M and P are positive integers greater than 2, arranged to respond to light incident on the photosensitive image region (1);
a storage region (2) arranged not to respond to incident light, the storage region comprising M columns of N storage elements, arranged to transfer data along the M columns of storage from a respective one of the M pixels along column of N storage elements; and
a readout section (3) arranged to read out data from the M columns of the storage region; and
circuitry (12,16) for controlling the time of flight sensor (6) to capture image data of the pulsed illumination stripe along a row of pixels and to transfer the captured image data to the storage section;
wherein the circuitry is arranged to adjust the phase of the clocking of the image region with respect to the step of emitting a pulsed fan beam to collect a plurality of image illumination stripes at a respective plurality of phase shifts; and
a processor (13,17) arranged to combine the data from the plurality of image illumination stripes at the plurality of phase shifts to determine the distance to the object.

9. A time of flight distance measurement system according to claim 8, wherein the time of flight sensor is a charge coupled device.

10. A time of flight distance measurement system according to claim 8, wherein photons incident over at least 90% of the area of the photosensitive image region are captured.

11. A computer program product, arranged to control a time of flight distance measurement system, the computer program product causing:
(i) a light emitter to emit a pulsed fan beam to illuminate a remote object with an object illumination stripe;
(ii) a time of flight sensor to capture an image of the object illumination stripe as an image illumination stripe on a photosensitive image region (8) of the time of flight sensor, the photosensitive image region comprising an array of M columns of J rows of pixels, where both M and J are positive integers greater than 2;
(iii) data to be transferred from the photosensitive image region (1,50) to a storage region (2) arranged not to respond to incident light, the storage region comprising M columns of S storage elements, along the M columns of the storage region from respective columns of the photosensitive image region at a transfer frequency F_{T};
(iv) data to be read out in a readout section (3) from the M columns of the storage region (2); and
(v) the image region to be clocked at a dock frequency while capturing the image of the object illumination stripe;
(vi) adjustment to the phase of the clocking of the image region with respect to causing the light emitter to emit a pulsed far beam to collect a plurality of image illumination stripes at a respective plurality of phase shifts;
(vii) the data to be read out from the plurality of image illumination stripes from the image region (1,50) via the storage region and the readout section; and
(viii) the data to be combined from the plurality of image illumination stripes at the plurality of phase shifts to determine the distance to the object.
